(19) United States
(12) Patent Application Publication
(10) Pub. No.: US 2018/0219511 A1
(43) Pub. Date: Aug. 2, 2018

(54) SOLAR POWER SYSTEM

(71) Applicant: SOLARTECHNO EUROPE B.V., Noordwijk (NL)

(72) Inventor: Marco GHIRARDELLO, Noordwijk (NL)

(21) Appl. No.: 15/749,935

(22) PCT Filed: Aug. 4, 2016
(86) PCT No.: PCT/EP2016/068700

§ 371 Date: Feb. 2, 2018

(30) Foreign Application Priority Data
Aug. 5, 2015 (NL) 2015268

(51) Int. Cl. H02S 40/38; H01L 31/042; H02S 40/32; H02S 40/34; H02S 30/10

(52) U.S. Cl. CPC H02S 40/38; H01L 31/042; H02S 30/10; H02S 40/345; H02S 40/32

(57) ABSTRACT

A solar power system is disclosed, the system including a solar panel to generate electrical energy and a solar power module. The module includes at least one battery cell to store electrical energy and a passive thermal management component. The passive thermal management component at least partially encapsulates the at least one battery cell to dissipate thermal energy. The solar power module is disposed at a backside of the solar panel such that a convectional space is provided between a planar surface of the solar power module and the backside of the solar panel. A Peltier element may be used in addition to the passive thermal management component.

### BACKGROUND

Solar power panels are used for the local generation of electrical energy for both domestic as well as commercial applications. In urban areas these can be used in addition to the electrical infrastructure i.e. the existing grid for powering domestic appliances on demand, while allowing an excess of generated energy not consumed to be delivered to the grid. These solar power panels may also be used off-grid, e.g. for powering an electrical system or appliance at a remote location. In off-grid applications solar power panels may typically be connected to storage systems such as battery packs. However, for delivery of continuous high-demand performance in remote rural areas diesel generator sets are used which are costly in operation and costly to the environment.

### SUMMARY

It is an object of the invention to provide a self-contained solar power system. This may be obtained by a solar power system comprising a solar panel to generate electrical energy and a solar power module. The solar power module comprises at least one battery cell to store electrical energy and a passive thermal management component. The passive thermal management component encapsulates or at least partially encapsulates (or surrounds) the at least one battery cell to dissipate thermal energy.

According to an aspect, there is provided a solar power system comprising a solar panel to generate electrical energy and a solar power module. The module comprises at least one battery cell to store electrical energy and a passive thermal management component. The passive thermal management component at least partially encapsulates the at least one battery cell to dissipate thermal energy. The solar power module is disposed at a backside of the solar panel such that a convectional space is provided between a planar surface of the solar power module and the backside of the solar panel.

The solar power module may further comprise a charge controller to control charging and discharging of the at least one battery cell with the electrical energy generated by the solar panel.

The solar power module may further comprise a converter to convert the electrical energy generated and/or stored by the module to a predetermined electrical output.

The solar power module may further comprise a battery management system.

The battery management system may be configured to perform at least one of the following: disconnect the battery when a failure is detected, balance a charge level of at least two battery cells, monitor battery temperature and/or battery cell temperature, prevent overcharging, prevent overdischarging, limit discharging current, monitor a charge state of the battery, enable deep battery discharge protection, and/or put the battery in long term storage mode.

The solar power module may have a planar surface that fits within a planar surface of the solar panel.

The solar panel may be disposed against the solar power module.

The passive thermal management component may at least partially encapsulate a plurality of battery cells.

The passive thermal management component may comprise phase change material.

The solar panel may comprise solar cells of a photovoltaic type. The solar power module may further comprise at least one Peltier element.

The at least one battery cell may be of the lithium ion type, such as Lithium Nickel Cobalt Aluminum Oxide (NCA), Lithium-Sulfur, Lithium-Air, Lithium Iron Phosphate and Lithium Titanate type.

The backside of the solar panel may be connected to the planar surface of the solar power module by two or more spaced supports.

The backside of the solar panel may comprise a backsheet to which the solar cells are laminated.

The backsheet may comprise a metal backsheet.

The convectional space may be provided between the planar surface of the solar power module and the backside of the backsheet.

The system may be configured as a roof-integrated solar power system.

According to another aspect, there is provided a solar power module. The module comprises at least one battery cell to store electrical energy and a passive thermal management component. The passive thermal management component at least partially encapsulates the at least one battery cell to dissipate thermal energy and the solar power module is configured to be disposed at a backside of a solar panel such that a convectional space is provided between a planar surface of the solar power module and the backside of the solar panel.

### BRIEF DESCRIPTION OF THE DRAWINGS

The present disclosure will be illustrated by examples described in the following detailed description and in reference to the drawings, wherein:

FIG. 1 shows a perspective view of an example of a solar power module;

FIG. 2 shows a top view of the solar power module of FIG. 1;

FIG. 3 shows a perspective view of a solar power system;

FIGS. 4A and 4B show a cross-section of another example of a solar power system;

FIG. 5 shows a cross-section along line A-A′ of the solar power system of FIG. 3;

FIG. 6 shows a perspective view of another example of a solar power module;

FIG. 7 shows a perspective view of another example of a solar power system; and

FIG. 8 shows a view of another example of a solar power system.

### DETAILED DESCRIPTION

Solar power panels implement the photovoltaic effect to convert energy from the sun into an electrical current. A panel is made up of multiple solar cells that each provide a contribution to the overall electrical output of the solar power panel. This generated power then needs to be converted to the required electrical mode of Alternate or Direct Current, and the desired Voltage level, depending on the intended application.

Accordingly, for the proper supply of electrical power a number of additional components is necessary to be installed together with a solar panel.

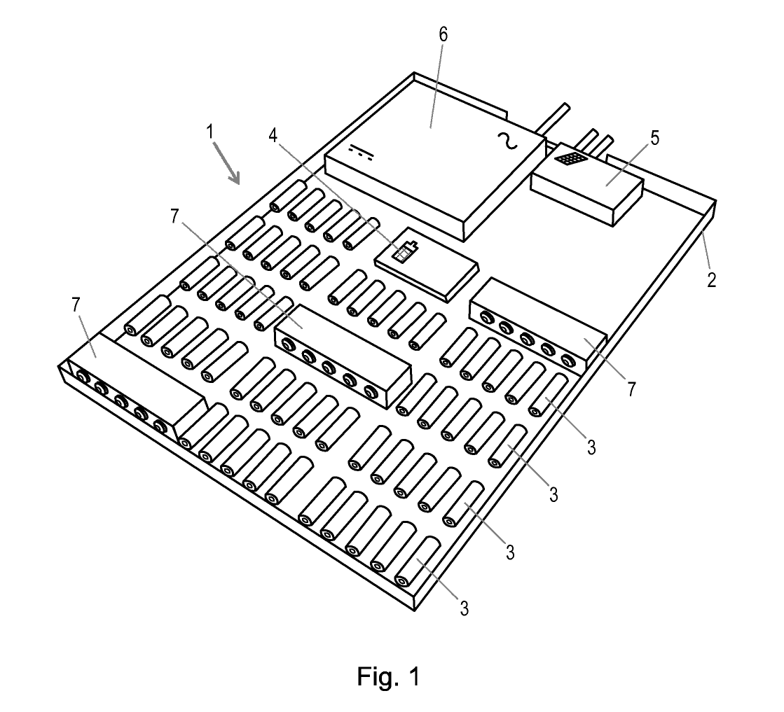

FIG. 1 shows an example of a solar power module 1 that may be used in combination with a solar power panel. In this example, the module has a rectangular housing 2 which accommodates a plurality of battery cells 3, a battery management system 4, a charge controller 5 and a converter 6. The battery cells 3, in this example of the lithium-ion type such as, but not limited to, Lithium-ion Nickel Cobalt Aluminum Oxide (NCA), are encapsulated or at least partially surrounded by a passive thermal management component 7. Other type of batteries may be used, such as, but not limited to, solid state batteries, Lithium-Sulfur, Lithium-Air, Lithium Iron Phosphate or Lithium Titanate type. The passive thermal management component dissipates thermal energy. Though the passive thermal management component 7 is shown only encapsulating only a number of battery cells 3, in the finished product all battery cells will be encapsulated.

The battery charge controller 5 controls charging and discharging of the plurality of battery cells 3 with the electrical energy generated by a solar panel. The battery management system 4 manages the safe operating conditions of the plurality of battery cells 3. The converter 6 converts the electrical energy generated and/or stored by the module to a desired predetermined electrical output. In this example, the battery cells 3 are arranged in clusters i.e. packs of five, but any suitable or convenient arrangement may be applied.

In one example, the battery management system may be configured to perform further functions. For example, to disconnect the battery when a failure is detected, balancing the charging levels of two or more battery cells, monitoring battery temperature, prevent overcharging, prevent overloading, limit discharging current, monitor a charge state of the battery, enable deep battery discharge protection, and/or put the battery in long term storage mode.

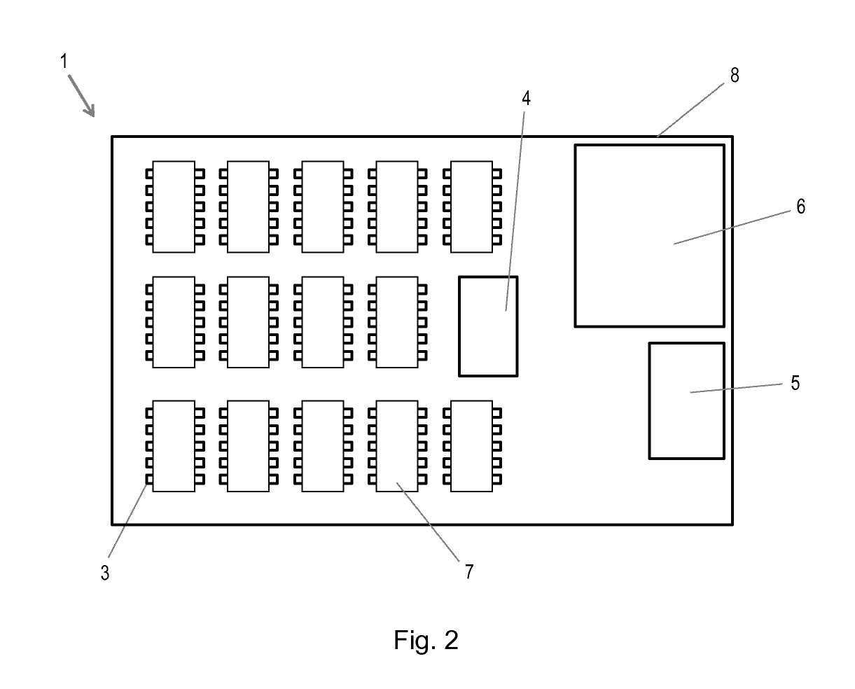

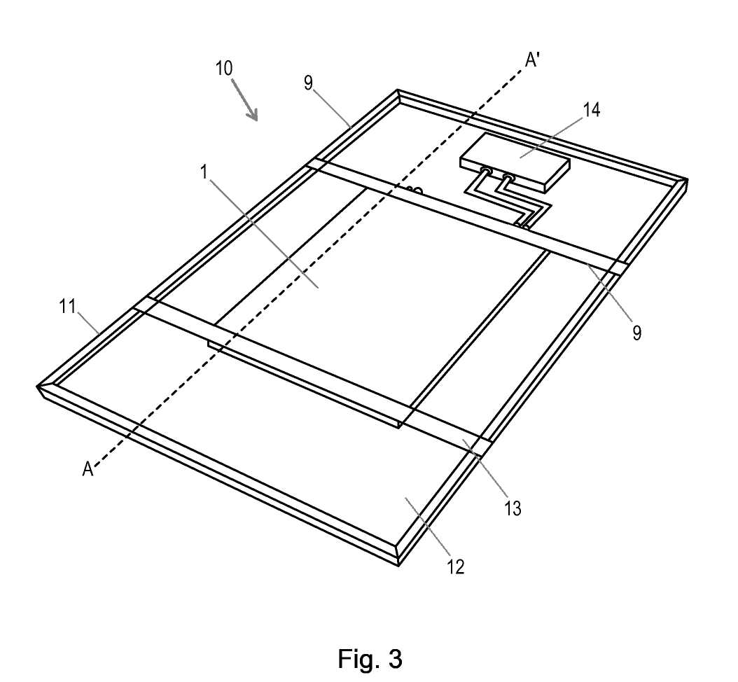

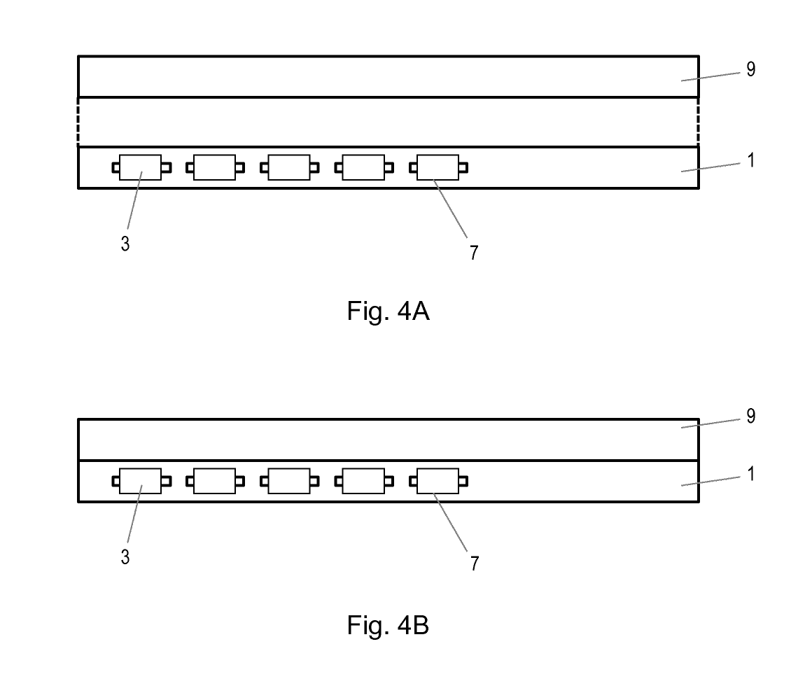

FIG. 2 is a top view of the solar power module 1 of FIG. 1, and shows the solar power module 1 having a rectangular outer perimeter 8. The outer perimeter 8 spans a planar surface of which the dimensions are designed such that they substantially fit within the dimensions of a planar surface of a solar panel 9 which the module is intended to be combined with, as shown in FIG. 3. In another example, shown in FIGS. 4A, 4B, the dimensions of the solar panel 9 may substantially match the dimensions of the solar power module 1. The solar panel 9 may be positioned over the solar power module 1 and consecutively moved towards the power module 1 along the dotted lines to be disposed against or adjacent the module 1. Thus, a solar power system is obtained.

Returning to FIG. 3, a solar power system 10 is shown that is assembled by disposing the solar power module 1 to a backside 12 of the solar panel 9. The solar panel 9 has a support frame 11. In this example, the solar power module 1 is fixed by means of two cross-bars 13 of the support frame 11 that span the backside 12 of the solar panel 9. The solar power module 1 is electrically connected to a junction box 14 of the solar panel 9.

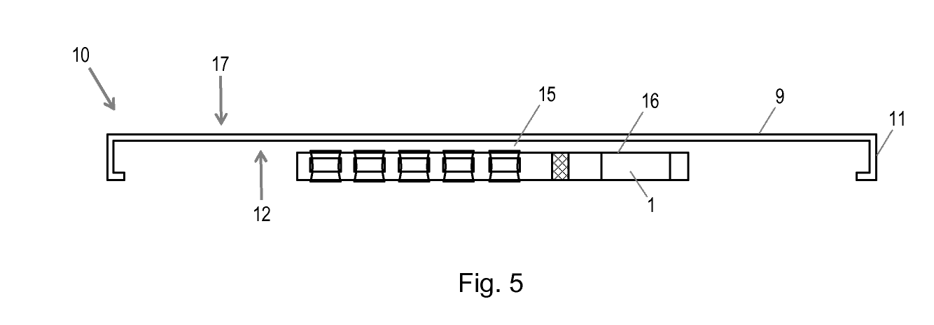

Referring to FIG. 5, the solar power system 10 of FIG. 3 is shown in cross-section along the line A-A′. The solar cells are located at one face of the solar panel 9 where sunlight may impinge, defining a front side 17 of the solar panel 9. In this example, the dimensions of the solar power module 1 are designed such that when the solar power module 1 is disposed at the backside 12 of the solar panel 9, a convectional space 15 is provided between a planar surface 16 of the solar power module 1 and the backside 12 of the solar panel 9. The convectional space 15 allows free movement of air therethrough, thereby allowing convective heat transfer.

Furthermore, in this example, a thickness of the solar power module 1 is such that when the solar power module 1 is disposed at the backside 12 of the solar panel 9, the module does not extend beyond a thickness of the support frame 11.

As described above, the solar power module 1 and solar panel 9 may be joined together thereby creating a self-contained integrated solar power system 10 that is ready for use. Multiple solar power systems 10 may be used as building blocks and combined to form an array of solar power systems.

In operation, the front side 17 of the solar power panel 9 containing the solar cells is exposed directly to the sun and may experience temperatures well above 60° C. and even up to 100° C. At the backside 12 of the solar panel 9, which faces the solar power module, the temperature may increase up to 75° C. and even 85° C. or above.

Thus far, this has prevented placing additional components in close proximity of solar panels in order to protect these components from excessive heat or even overheating. Accordingly, these additional components required to supply electrical power are disposed as separate units located at a distance from solar panels. In particular, the operation of battery cells is adversely affected by temperatures rising above specified operating conditions. For example, most manufacturers of solar power panels pose warranty limits regarding temperature operating conditions ranging from −20° C. to +85° C. This may reduce for example the performance as expressed in capacity, the life expectancy or the speed of charging and/or discharging of the battery cells.

The life expectancy may be expressed as cycle life in charge/decharge cycles or as calendar life in years. For example, the life expectancy of a battery cell operating at 10° C. above specified optimal operating conditions (which typically may be 25° C.) is halved. Thus, if for a Lithium NCA battery operating between 30% and 90% of full capacity the cycle life for example is 6000 cycles, then the same battery operating at 35° C. will have a reduced cycle life of 3000 cycles; and at 45 ° C. an even more reduced cycle life of 1500 cycles.

Calendar life, the life expectancy expressed in years, is also negatively affected by high storage temperature. Battery life is particularly affected by peak temperature when charging and discharging. Therefore limiting batteries peak temperatures during mid of the day hours when the solar panel is charging the batteries considerably prolongs the battery life. Battery cells operating conditions temperature limits are depending on the type of batteries, depth of discharge (DoD), and the required cycle life and calendar life.

The passive thermal management component 7 prevents the temperature at which the batteries operate from rising above appropriate operating conditions. The passive thermal management component 7 absorbs the heat stemming from the back of the solar panel and from the surroundings, especially during the hottest hours of the day (for example from 09.00 AM to 17.30 PM) and releases the absorbed energy to the surroundings during the cooler hours of the day (night) when the surrounding temperature is below the temperature of the passive thermal management component. This allows the passive thermal management component to be ready to start again the absorption of thermal energy at the beginning of the next 24 hours cycle.

The passive thermal management component 7 comprises phase change material. Suitable phase change materials for the solar power module are: materials whose main component is paraffin and materials whose main component are salts. The type of application of the solar power system, for example military with high temperature requirements, but low life cycle expectations or residential with long life requirements, but lower temperature limits, and the local climate, for example desert or temperate climate, will determine the requirements for a suitable phase change material. For example, a solar power module intended for use in residential applications may be fitted with a paraffin based phase change material with a melting temperature around 37° C.

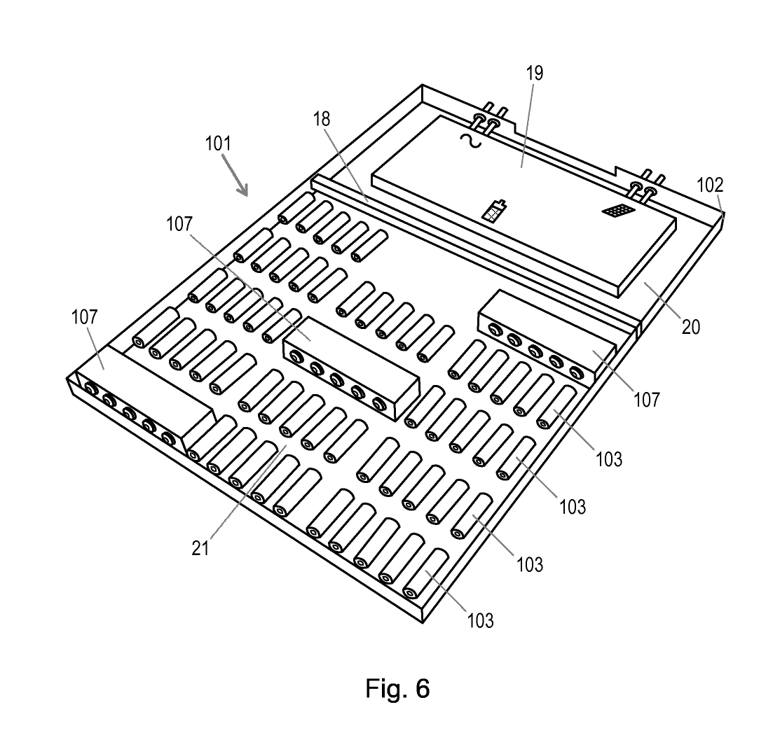

FIG. 6 shows another example of a solar power module 101, wherein the battery management system, the charge controller and the converter are disposed within a single box 19. Furthermore, the battery management system, the charge controller and the converter may be implemented on a single printed circuit board. As in FIG. 1, the solar power module 101 has a rectangular housing 102 which accommodates a plurality of battery cells 103, which are encapsulated or at least partially surrounded by a passive thermal management component 107. The solar power module is further provided with a divider 18, dividing the inner part of the housing 102 in a battery compartment 20 and an electronics compartment 21. The divider may act as a heat shield preventing heat transfer between the battery compartment 20 and the electronics compartment 21.

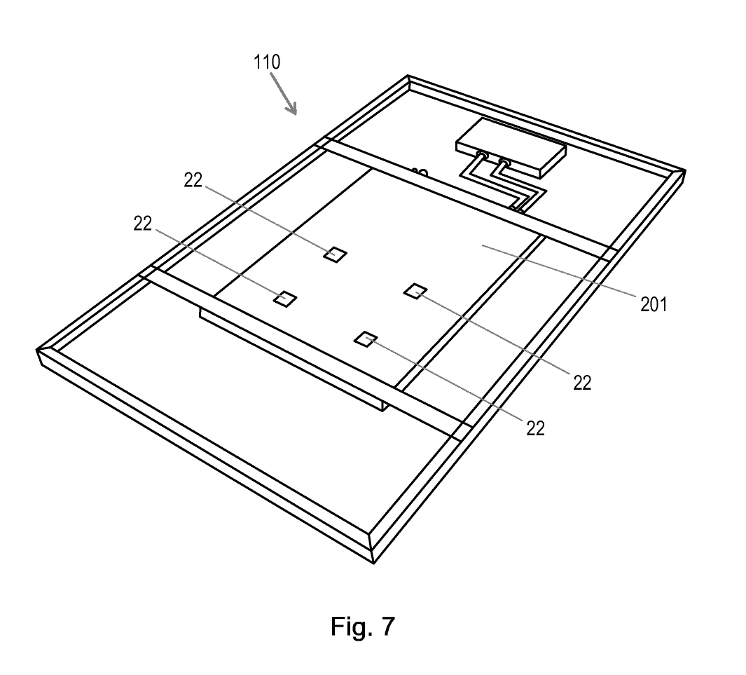

FIG. 7 shows yet another example of a solar power system 110. In this example, the solar power module 201 is further provided with four Peltier elements 22. These Peltier elements may provide additional heat dissipation during peak temperatures.

For example, when the passive thermal management component has dissipated thermal energy to full capacity, amidst peak temperature, the Peltier element can support further dissipation of thermal energy. For example, when phase change material is applied, and the temperature has risen well above the characteristic temperature thereof, such that all phase change material has changed phase, the Peltier elements may provide further dissipation of thermal energy.

In general, phase change materials have low conductivity in solid state. While with rising temperature, as the material dissipates thermal energy during the change of phase towards a more fluid-like state, the conductivity rises. Thus, when the surrounding temperature starts to rise, as for example in the morning, and the phase change material is still in solid state, it has a low conductivity and provides thermal insulation for the battery cells. When the surrounding temperature rises further, the phase change material may in extreme conditions change fully into the fluid-like state. In such extreme conditions, which might occur in desert or other harsh environments, the addition of Peltier elements may provide further benefits. Moreover, as the phase change material has a higher conductivity during peak temperatures, the thermal energy may be transferred more conveniently to the Peltier elements.

Accordingly, as the conductive properties of phase change materials improve with rising temperature and decrease with lowering temperature, the additional dissipation of heat by Peltier elements during peak temperature is more easily obtained due to the increased conductivity of the phase change material. Thus, the additional use of Peltier elements supports the passive temperature management component in phase with the daily thermal cycle of solar power.

In one example, the battery management system 4 may be further configured to activate one or more Peltier elements 22 in response to the conductivity of the passive management component 7. Or in another example, the battery management system 4 may be further configured to activate one or more Peltier elements 22 in response to the state of phase change material.

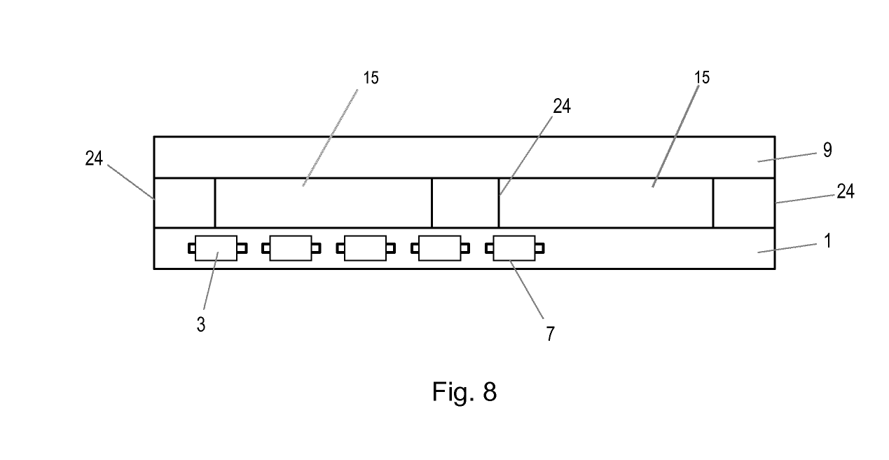

In another example, shown in FIG. 8, the dimensions of the solar panel 9 may substantially match the dimensions of the solar power module 1. The solar panel 9 may be positioned over the solar power module 1 and spaced from the power module 1 by supports 24 to form a solar power system. In this particular example, three supports, are provided. The supports 24 may be elongate support struts that are the same length or width as the solar panel 9, or a series of short support columns. Depending on the form of the supports, the number and spacing of the supports may vary dependent on the size of the solar panel and solar power module, and the materials used. Supports 24 provide the convectional space 15 between the planar surface of the solar power module 1 and the solar panel 9.

The height of supports 24 (and therefore the height of the convectional space 15) may vary, but will typically be less than 10 cm, for example less than 5 cm, for example about 2 cm. In one example, support struts 24 are formed from a metal, for example aluminium. The supports 24 may be integrally formed with an external planar surface of the solar power module 1, or integrally formed with the solar panel 9, or separately formed and fixed in place between the solar power module 1 and the solar panel 9.

In one example, solar panel 9 comprises a backsheet which faces the solar power module 1, and which supports the rest of the solar panel 9. In one example, the backsheet of the solar panel is formed from a metal, for example aluminium.

The configuration or structure of the solar panel 9 may vary, but will typically include the backsheet, an optional layer of polymeric material such as polyvinyl fluoride on the backsheet, a lower encapsulating film, typically ethylene vinyl acetate, to laminate the solar cells to the underlying layer, followed by the solar cells themselves and an upper encapsulating film, again typically ethylene vinyl acetate. A final face plate is provided at the weather-facing surface to provide protection from the elements. The face plate is typically glass, but in some examples polymeric materials such as poly(methyl methacrylate) (commercially available as Plexiglas®), polyethylene, polycarbonate (commercially available as Lexan™) or ethylene tetrafluoroethylene may also be used.

By fixing the backsheet of the solar panel 9 to the solar power module 1 using supports 24, a fully integrated solar power system is formed which is compact, and easy to transport. In some examples, a separate support frame for the solar panel 9 in such solar power systems is no longer required. The convectional space 15 resulting from the use of supports 24, lowers the temperatures of the solar panel 9 and/or solar power module 1, and contributes to the cooling of the system along with the passive thermal management component, and the Peltier elements, when present. The system described herein is therefore advantageous for dissipating thermal energy generated by a hotspot due to an increase in resistance in a faulty or inefficient solar cell, or due to the heat produced by a microinverter on the backside of the solar panel 9.

The thus obtained solar power system as described above provides lower cost of storing due to volume reduction and/or lower costs of energy storage as compared to e.g. diesel operated generators. It further provides higher storage efficiency due to the compact design format that may be obtained, and higher efficiency of operation due to the thermal management features described.

The solar power system as described therefore finds particular use in numerous settings where the harnessing of solar power is desirable. While other situations will be apparent, one particular example is the installation of the solar power system on rooves of domestic or commercial premises. The solar power system described is particularly useful in so-called roof-integrated solar systems, in which a solar panel is configured as a roof tile designed to be built into a roof, rather than sitting on top of the roof. Thermal management of such roof-integrated systems is important as the operating temperatures of such systems, are typically higher than stand-alone solar panels mounted onto existing roof tiles.

In the foregoing description, numerous details are set forth to provide an understanding of the examples disclosed herein. However, it will be understood that the examples may be practiced without these details. For example, the solar power module may be used in combination with various solar panels of different sizes and performance levels. While a limited number of examples have been disclosed, numerous modifications and variations therefrom are contemplated. It is intended that the appended claims cover such modifications and variations.

1. A solar power system, comprising:
a solar panel to generate electrical energy; and
a solar power module, the module comprising:
at least one battery cell to store electrical energy; and
a passive thermal management component;
wherein the passive thermal management component at least partially encapsulates the at least one battery cell to dissipate thermal energy and the solar power module is disposed at a backside of the solar panel such that a convectional space is provided between a planar surface of the solar power module and the backside of the solar panel.

2. A system according to claim 1, the solar power module further comprising a charge controller to control charging and discharging of the at least one battery cell with the electrical energy generated by the solar panel.

3. A system according to claim 1, the solar power module further comprising a converter to convert the electrical energy generated and/or stored by the module to a predetermined electrical output.

4. A system according to claim 1, the solar power module further comprising a battery management system.

5. A system according to claim 4, wherein the battery management system is configured to perform at least one of the following:
disconnect the battery when a failure is detected;
balance a charge level of at least two battery cells;
y onf monitor battery temperature and/or battery cell temperature;
prevent overcharging;
prevent overdischarging;
limit discharging current;
monitor a charge state of the battery;
enable deep battery discharge protection; and/or put the battery in long term storage mode.

6. A system according to claim 1, wherein the solar power module has a planar surface that fits within a planar surface of the solar panel.

7. A system according to claim 1, wherein the solar panel is disposed against the solar power module.

8. A system according to claim 1, wherein the passive thermal management component at least partially encapsulates a plurality of battery cells.

9. A system according to claim 1, wherein ithe passive thermal management component comprises phase change material.

10. A system according to claim 1, wherein the solar panel comprises solar cells of a photovoltaic type.

11. A system according to claim 1, the solar power module further comprising at least one Peltier element.

12. A system according to claim 1, wherein the at least one battery cell is of the lithium ion type, such as Lithium Nickel Cobalt Aluminum Oxide (NCA), Lithium-Sulfur, Lithium-Air, Lithium Iron Phosphate and Lithium Titanate type.

13. A system according to any one of the preceding claims claim 1, wherein the backside of the solar panel is connected to the planar surface of the solar power module by two or more spaced supports.

14. A system according to claim 1, wherein the backside of the solar panel comprises a backsheet to which the solar cells are laminated.

15. A system according to claim 14, wherein the backsheet comprises a metal backsheet.

16. A system according to claim 14 or claim 15, wherein the convectional space is provided between the planar surface of the solar power module and the backside of the backsheet.

17. A system according to any one of the preceding claims claim 1, wherein the system is configured as a roof-integrated solar power system.

18. A solar power module, the module comprising:
at least one battery cell to store electrical energy; and
a passive thermal management component;
wherein the passive thermal management component at least partially encapsulates the at least one battery cell to dissipate thermal energy and the solar power module is configured to be disposed at a backside of a solar panel such that a convectional space is provided between a planar surface of the solar power module and the backside of the solar panel.
